(19) United States
(12) Patent Application Publication
(10) Pub. No.: US 2014/0361223 A1
(43) Pub. Date: Dec. 11, 2014

(54) Composite and Molded Product Thereof

(71) Applicant: Cheil Industries Inc., Gumi-si (KR)

(72) Inventors: Jee Kwon Park, Uiwang-si (KR); Yoon Sook Lim, Uiwang-si (KR); Jae Hyun Han, Uiwang-si (KR); Kang Yeol Park, Uiwang-si (KR)

(21) Appl. No.: 14/362,642

(22) PCT Filed: Dec. 4, 2012
(86) PCT No.: PCT/KR2012/010423

§ 371 Date: Jun. 4, 2014

(30) Foreign Application Priority Data
Dec. 9, 2011 (KR) 10-2011-0132315
Dec. 27, 2011 (KR) 10-2011-0143776
Dec. 29, 2011 (KR) 10-2011-0146570

(51) Int. Cl. H05K 9/00

(52) U.S. Cl. CPC H05K 9/009
USPC 252/478

(57) ABSTRACT

A composite of the present invention comprises: about 10 wt % to about 84 wt % of (A) a thermoplastic resin; about 5 wt % to about 35 wt % of (B) a first filler; about 1 wt % to about 20 wt % of (C) a second filler; and about 10 wt % to about 60 wt % of (D) a third filler, wherein the third filler (D) is a conductive filler, and the melting points of the thermoplastic resin (A), the first filler (B) and the second filler (C) satisfy the following relation 1:

Tma−30° C.>Tmb,Tma+500° C.<Tmc [Relation 1]
(wherein, Tma is the melting point (° C.) of the (A) thermoplastic resin, Tmb is the melting point (° C.) of the (B) first filler, and Tmc is the melting point (° C.) of the (C) second filler).

### TECHNICAL FIELD

The present invention relates to a composite and a molded product thereof. More particularly, the present invention relates to a high-rigidity electromagnetic shielding composite, which has excellent processability and can replace existing metallic materials to reduce manufacturing costs by securing excellent mechanical strength and EMI shielding properties, and a molded product thereof.

### BACKGROUND ART

Electromagnetic waves are noise generated due to electrostatic discharge, and are known not only to have harmful effects on the human body, but also to cause surrounding components or apparatuses to suffer from noise and malfunction. Recently, a possibility of generation of electromagnetic waves is rapidly increasing due to high-efficiency, high-power consumption and high-integration electric/electronic products, and many countries including Korea are strengthening regulations on electromagnetic waves.

Typically, metallic materials have been used to shield electromagnetic waves in the art. For example, since an IT bracket used in portable displays, such as mobile phones, notebooks, PDAs, and other mobile items, protects an LCD, shields electromagnetic waves, and serves as a frame, the IT bracket requires high rigidity and EMI shielding properties. Recently, a metal, such as magnesium, aluminum, stainless steel and the like, is mainly used as a material for brackets, frames and the like. However, although such a metal can effectively shield electromagnetic waves, a product is produced from the metal through die-casting, thereby causing high manufacturing costs and high failure rate.

Therefore, a method for replacing metal with a thermoplastic resin, which can be easily molded and provides excellent molding precision, economic efficiency and productivity, has been proposed.

Since an existing thermoplastic resin replacing metal has a flexural strength of 20 GPa or less and an electromagnetic shielding effectiveness of about 30 dB (@ 1 GHz), the existing thermoplastic plastic exhibits much lower rigidity and EMI shielding properties than metal. An attempt has been made to improve flexural strength by increasing fiber content. However, this method has a problem in that a high-fiber content thermoplastic plastic for replacing metal is difficult to practically use due to insufficient properties in terms of impact strength, fluidity and processability, and is difficult to use as a material for electronic devices due to extremely low conductivity and high surface resistance.

Recently, although a product having high modulus and an electromagnetic shielding effectiveness of 30 dB or more is developed using 50% or more of carbon fibers, the product is insufficient to replace metal and has a difficulty in processing. In addition, such a material has a problem in use as a material for electronic devices due to low conductivity thereof. For example, when the material is applied to a general mobile phone bracket, there is a problem of deterioration in grounding performance and antenna performance.

Although a general high-rigidity resin is subjected to conductive plating to reduce surface resistance in order to resolve the above problem, there is a problem of cost increase due to plating, post-processes and the like, and the resin can surfer from surface peeling when used for a long period of time.

Therefore, there is a need for a novel material, which has excellent properties in terms of fluidity, impact strength, rigidity, conductivity and electromagnetic shielding properties, and thus can replace existing metals.

### DISCLOSURE

### Technical Problem

It is one aspect of the present invention to provide a composite, which can replace metal and be used as a material for electronic devices and the like, and a molded product thereof.

It is another aspect of the present invention to provide a composite, which exhibits outstanding processability such as injection moldability, high flexural strength, low surface resistance, high electrical conductivity and high electromagnetic shielding properties, and a molded product thereof.

It is a further aspect of the present invention to provide a composite, which does not require post-processing and provides outstanding economic efficiency and productivity, and a molded product thereof.

It is yet another aspect of the present invention to provide a composite exhibiting excellent dimensional stability, and a molded product thereof.

It is yet another aspect of the present invention to provide a composite, which has improved product competitiveness through improved productivity and reduced manufacturing costs, and a molded product thereof.

### Technical Solution

In accordance with one aspect of the present invention, a composite includes: about 10% by weight (wt %) to about 84 wt % of (A) a thermoplastic resin; about 5 wt % to about 35 wt % of (B) a first filler; about 1 wt % to about 20 wt % of (C) a second filler; and about 10 wt % to about 60 wt % of (D) a third filler, wherein the first filler is a metal having a lower melting point than the thermoplastic resin, the second filler is a metal having a higher melting point than the thermoplastic resin, and the third filler is a conductive fiber.

In one embodiment, the (A) thermoplastic resin, the (B) first filler and the (C) second filler may have melting points satisfying Relation 1:

Tma−30° C.>Tmb,Tma+500° C.<Tmc [Relation 1]

(wherein, Tma is the melting point (° C.) of the (A) thermoplastic resin, Tmb is the melting point (° C.) of the (B) first filler, and Tmc is the melting point (° C.) of the (C) second filler).

The third filler may be present in an amount of about 1 to about 4 times the total amount of the first and second fillers.

The third filler may be present in an amount of greater than the total amount of the first and second fillers.

The second filler may exhibit higher electrical conductivity than the first filler.

The first and second fillers may have a powder or fiber form.

The composite may have a weight ratio of the (B) first filler to the (C) second filler from about 1:1 to about 3:1.

The third filler may be carbon fiber or surface-treated carbon fiber.

The surface-treated carbon fiber may be carbon fiber having a surface subjected to coating with a metal or sizing with a resin.

The metal coated onto the carbon fiber may include at least one selected from the group consisting of aluminum, stainless steel, iron, chrome, nickel, black nickel, copper, silver, gold, and platinum.

The third filler may have a diameter from about 3 μm to about 10 μm.

The (A) thermoplastic resin may be a crystalline thermoplastic resin.

The (A) thermoplastic resin may include at least one of polyacetal, acrylic, polycarbonate, aromatic vinyl, polyester, vinyl, polyphenylene ether, polyolefin, acrylonitrile-butadiene-styrene copolymer, polyarylate, polyamide, polyamideimide, polyether, polysulfide, polyarylsulfone, polyetherimide, polyethersulfone, polyphenylene sulfide, fluorine, polyimide, polyetherketone, polybenzoxazole, polyoxadiazole, polybenzothiazole, polybenzimidazole, polypyridine, polytriazole, polypyrrolidine, polydibenzofuran, polysulfone, polyurea, polyphosphazene, and liquid crystal polymer resins.

The composite may further include at least one additive selected from the group consisting of flame retardants, plasticizers, coupling agents, heat stabilizers, light stabilizers, release agents, dispersants, anti-dripping agents, and weather-resistant stabilizers.

The (D) third filler may be present in an amount of greater than or equal to the amount of the (A) thermoplastic resin.

The composite may further include (E) a functional group-containing impact modifier.

The (E) impact modifier may be functionalized through graft polymerization with maleic anhydride, glycidyl (meth)acrylate, (meth)acrylic acid, or oxazoline.

The first filler may have a lower melting point than the second filler by about 700° C. or more.

Another aspect of the present invention relates to a molded product of the above composite. The molded product has a structure in which a thermoplastic resin forms a continuous phase; a dispersed phase including the first, second and third fillers is dispersed in the continuous phase; the first filler has a lower melting point than the second filler by about 700° C. or more; and the first filler continuously or discontinuously surrounds a surface of the second filler.

In one embodiment, the molded product may have: a flexural modulus of about 25 GPa or more, as measured on a 3.2 mm thick specimen in accordance with ASTM D790; an EMI shielding effectiveness of about 40 dB or more, as measured at 1 GHz in accordance with ASTM D257; and a surface resistance of about 5.0Ω·cm or less.

### Advantageous Effects

The present invention provides a composite, which is suitable for EMI shielding by securing outstanding mechanical strength and conductivity and low surface resistance, exhibits excellent properties in terms of fluidity, moldability, economic efficiency, productivity and dimensional stability, does not require post-processing, and can replace existing metals, and a molded product thereof.

### DESCRIPTION OF DRAWINGS

FIG. 1 is a schematic diagram of a composite according to one embodiment of the present invention.

FIG. 2 is a schematic diagram of a composite according to another embodiment of the present invention.

FIG. 3 shows (a) a scanning electron microscope (SEM) image of a surface of a specimen of Comparative Example 1, and (b) an energy dispersive spectroscopy (EDS) image of a surface of copper (Cu).

FIG. 4 shows (a) an SEM image of a surface of a specimen of Example 1, (b) an EDS image of a surface of tin (Sn), and (c) an EDS image of a surface of copper (Cu).

### BEST MODE

According to the present invention, a composite includes: (A) a thermoplastic resin; (B) a first filler; (C) a second filler; and (D) a third filler.

Hereinafter, the components of the composite will be described in detail with reference to the accompanying drawings.

(A) Thermoplastic Resin

According to the present invention, the thermoplastic resin may be any thermoplastic resin without limitation. For example, the thermoplastic resin may include polyacetal, acrylic, polycarbonate, aromatic vinyl, polyester, vinyl, polyphenylene ether, polyolefin, acrylonitrile-butadiene-styrene copolymer, polyarylate, polyamide, polyamideimide, polyether, polysulfide, polyarylsulfone, polyetherimide, polyethersulfone, polyphenylene sulfide, fluorine, polyimide, polyetherketone, polybenzoxazole, polyoxadiazole, polybenzothiazole, polybenzimidazole, polypyridine, polytriazole, polypyrrolidine, polydibenzofuran, polysulfone, polyurea, polyphosphazene, and liquid crystal polymer resins, without being limited thereto. These may be used alone or in combination thereof.

Preferably, the thermoplastic resin is a crystalline thermoplastic resin, more preferably a polyamide resin or a polyester resin.

The polyamide resin may include aliphatic polyamide resins, aromatic polyamide resins including an aromatic group in a backbone thereof, and copolymers or mixtures thereof. In one embodiment, the polyamide resin may include NYLON 6, NYLON 66, NYLON 46, NYLON 610, NYLON 612, NYLON 66/6, NYLON 6/6T, NYLON 66/61, NYLON 6T, NYLON 9T, NYLON 10T, NYLON MXD6, and NYLON 6I/6T, without being limited thereto. Preferably, the polyamide resin is an aromatic polyamide resin containing an aromatic group in the backbone thereof. When the backbone contains the aromatic group, the composite can exhibit high rigidity and strength.

In one embodiment, the polyamide resin has a glass transition temperature (Tg) from about 60° C. to about 120° C., preferably from about 80° C. to about 100° C. Within this range, the composite can have balance between excellent fluidity, rigidity, and low moisture absorption.

In addition, the polyamide resin has a number average molecular weight from about 10,000 g/mol to about 200,000 g/mol, preferably from about 30,000 g/mol to about 100,000 g/mol. Within this range, the composite exhibits excellent properties in terms of both flowability and mechanical properties.

The polyester resin may include polyethylene terephthalate, polypropylene terephthalate, polybutylene terephthalate, and polyethylene naphthalate, without being limited thereto.

The polyacetal resin may be a polyoxymethylene resin, without being limited thereto.

The polycarbonate resin may include linear polycarbonate resins, branched polycarbonate resins, polyestercarbonate copolymers, and the like. Preferably, the polycarbonate resin is a bisphenol A-based polycarbonate.

The acrylic resin may include aromatic (meth)acrylate polymers, aliphatic (meth)acrylate polymers, and copolymers or mixtures thereof. In one embodiment, the acrylic resin may be a single polymer of methyl methacrylate, or a copolymer of methyl methacrylate and another vinyl monomer. The vinyl monomer may include: methacrylic acid esters including ethyl methacrylate, propyl methacrylate, butyl methacrylate, hexyl methacrylate, 2-ethylhexyl methacrylate, and benzyl methacrylate; acrylic acid esters including methyl acrylate, ethyl acrylate, propyl acrylate, butyl acrylate, hexyl acrylate, and 2-ethylhexyl acrylate; unsaturated carboxylic acids include acrylic acid and methacrylic acid; acid anhydrides including maleic anhydride; hydroxyl group-containing esters including 2-hydroxyethyl acrylate, 2-hydroxypropyl acrylate and monoglycerol acrylate, and the like.

The polyolefin resin may include polyethylene, polypropylene, polybutylene, and copolymers or mixtures thereof. In addition, the polyolefin resin may include atactic, isotactic and syndiotactic structures thereof.

The aromatic vinyl resin may include polystyrene, HIPS, ABS, SAN, ASA, MABS, and combinations thereof.

According to the present invention, the (A) thermoplastic resin forms a continuous phase and is present in an amount of about 10 wt % to about 84 wt %, for example, about 30 wt % to about 80 wt %, preferably about 35 wt % to about 75 wt %, more preferably about 35 wt % to about 55 wt % in the total composite. Within this range, the composite exhibits excellent properties in terms of modulus, strength, EMI shielding properties, and moldability.

(B) First Filler

According to the present invention, the (B) first filler may be a low melting point metal having a lower melting point than the (A) thermoplastic resin. Thus, when the (A) thermoplastic resin is subjected to processing, such as melt extrusion and the like, the (B) first filler is melted along with the (A) thermoplastic resin and surrounds the (C) second filler described below.

The (A) thermoplastic resin, the (B) first filler and the (C) second filler have melting points satisfying Relation 1:

Tma−30° C.>Tmb,Tma+500° C.<Tmc [Relation 1]

(wherein, Tma is the melting point (° C.) of the (A) thermoplastic resin, Tmb is the melting point (° C.) of the (B) first filler, and Tmc is the melting point (° C.) of the (C) second filler).

As such, the (B) first filler may have a solidus temperature (a temperature at which coagulation is terminated) lower than the melting point of the (A) thermoplastic resin. Preferably, the (B) first filler has a lower melting point than the (A) thermoplastic resin by about 30° C. or more. In this case, there is an advantage in preparation of the composite and formation of a network between the fillers, and the composite has an excellent effect of reduction in surface resistance since the (B) first filler is sufficiently aligned on a surface of the thermoplastic resin.

The (B) first filler may have a melting point from about 185° C. to about 300° C. Preferably, the (B) first filler has a melting point from about 190° C. to about 250° C., more preferably from about 200° C. to about 245° C. Within this range, the composite exhibits low surface resistance and excellent stability.

In addition, the (B) first filler may have an electrical conductivity, for example, from about 1.0×10⁶ s/m to about 10×10⁶ s/m. Within this range, the composite exhibits excellent shielding properties.

Examples of the (B) first filler may include bismuth, polonium, cadmium, gallium, indium, lead, tin, alloys thereof, and the like. Preferably, the (B) first filler is an alloy including a main component selected from the group consisting of tin, lead and combinations thereof, and a sub-component selected from the group consisting of copper, aluminum, nickel, silver, germanium, indium, zinc and combinations thereof. The first filler may be an alloy in which a high melting point metal is alloyed, and the melting point of the first filler should satisfy Relation 1.

The first filler may have any form without limitation. For example, the first filler may have a powder or fiber form, without being limited thereto.

According to the present invention, the (B) first filler is present in an amount of about 5 wt % to about 30 wt %, for example, about 7 wt % to about 27 wt %, preferably about 10 wt % to about 25 wt %, more preferably about 10 wt % to about 20 wt % in the total composite. Within this range, the composite has balance between conductivity, fluidity, impact strength, and flexural modulus.

(C) Second Filler

The second filler is not melted at a processing temperature of the thermoplastic resin, and includes a metal having a higher melting point than the thermoplastic resin. In one embodiment, the second filler may be a metal having higher conductivity and melting point than the (B) first filler, or be an inorganic material containing the above metal. Here, the term “inorganic material” includes any inorganic material excluding metals. Preferably, the second filler includes a metal having a higher melting point than the (B) first filler by about 700° C. or more. As such, since the second filler has a higher melting point than the thermoplastic resin by about 500° C. or more and the (B) first filler by about 700° C. or more, the second filler is not melted during processing and assists in dispersion of the first filler, thereby allowing the composite to exhibit excellent shielding properties.

In one embodiment, the (C) second filler may have a melting point of about 950° C. or more, for example, from about 1000° C. to about 2000° C.

In addition, the (C) second filler may have an electrical conductivity from about 1.0×10⁷ s/m to about 10×10⁷ s/m. Within this range, the composite exhibits excellent shielding properties.

Examples of the (C) second filler may include stainless steel, iron, chrome, nickel, black nickel, copper, gold, platinum, palladium, cobalt, titanium, vanadium, rhodium, alloys thereof, mixtures thereof, and the like. These may be used alone or in combination thereof. For example, the (C) second filler may be a mixture of at least two of these materials, or may be coated with at least one metal. In one embodiment, the (C) second filler may be an alloy of iron-chrome-nickel. The second filler may be an alloy in which a low melting point metal is alloyed, and the melting point of the second filler should satisfy Relation 1.

The (C) second filler may have a powder or fiber form. In one embodiment, the (C) second filler may have a metal powder form, spherical metals including metal beads, metal fibers, metal flakes, and metal dendrites, without being limited thereto. These may be used alone or in combination thereof. Preferably, the (C) second filler has a spherical or flake form.

When the (C) second filler has a metal powder or metal bead form, the (C) second filler may have an average particle diameter from 30 μm to 300 μm. Within this range, the composite can be easily fed when subjected to extrusion.

When the (C) second filler has a metal fiber form, the (C) second filler may have a length from about 0.1 mm to about 15 mm and a diameter from about 10 μm to about 100 μm. In addition, the metal fibers may have a density from about 0.7 g/ml to about 6.0 g/ml. Within this range, the composite can be suitably fed during extrusion.

When the (C) second filler has a metal flake form, the (C) second filler may have an average size from about 50 μm to about 500 μm. Within this range, the composite can be suitably fed during extrusion.

When the (C) second filler has a metal dendrite form, the (C) second filler may have an average size from about 5 μm to about 80 μm. Within this range, the composite exhibits improved electrical conductivity since networks between the filler and carbon fibers can be maintained.

A weight ratio of the (B) first filler to the (C) second filler ranges from about 1:1 to about 3:1, preferably from about 1.1:1 to about 2:1. Within this range, the composite exhibits excellent EMI shielding properties, high rigidity, and high impact resistance.

According to the present invention, the (C) second filler is present in an amount of about 1 wt % to about 20 wt %, for example, about 3 wt % to about 17 wt %, preferably about 5 wt % to about 15 wt %, more preferably about 10 wt % to about 15 wt % in the total composite. Within this range, the composite has balance between conductivity, fluidity, impact strength, and flexural modulus.

In addition, when the composite contains both the first and second fillers, an injection-molded product prepared therefrom has a surface resistance of about 5.0Ω or less and thus can exhibit high electrical conductivity.

(D) Third Filler

The third filler may be a conductive fiber. In one embodiment, the third filler may be carbon fiber or surface-treated carbon fiber.

The third filler has an average diameter from about 3 μm to about 10 μm, preferably from about 3.5 μm to about 7 μm. Within this range, the composite can exhibit excellent properties and conductivity. In addition, the third filler may have a length from about 4 μm to about 100 μm.

The third filler may be short fibers, long fibers, or rod-shaped fibers. In another embodiment, the third filler may be a bundle of fibers.

The surface-treated carbon fiber is carbon fiber having a surface subjected to sizing with a resin or coating with a metal.

In one embodiment, the carbon fiber may be prepared from PAN or pitch.

In one embodiment, the resin used in surface treatment of the carbon fiber may include urethane, polyamide, epoxy resins, and the like. Preferably, the resin is a polyamide or epoxy resin. Surface treatment of the carbon fiber with a specific resin facilitates dispersion of the carbon fiber and can reduce single yarns during processing, thereby improving properties of the composite, such as rigidity, electrical conductivity, and the like. Here, the resin has a sizing concentration from about 0.5% to about 7.5%, preferably from about 1% to about 5%. Within this range, the composite does not suffer from deterioration in processability or flexural modulus due to the single yarns of the carbon fiber, and exhibit excellent electrical conductivity due to formation of a network between carbon fibers. The sizing concentration may be measured through thermogravimetric analysis (TGA).

The (A) thermoplastic resin may be the same as the resin used in sizing. For example, when the (A) thermoplastic resin forming a continuous phase is a polyamide resin, the resin for sizing of the carbon fiber may be a polyamide resin. In addition, when the (A) thermoplastic resin forming a continuous phase is an epoxy or polyester resin, the resin for sizing of the carbon fiber may be an epoxy resin.

The carbon fiber may be coated with a metal. In this case, the metal may be coated to a thickness from about 30 nm to about 200 nm. Within this range, the carbon fiber does not suffer from detachment of the metal or formation of single yarns, and can exhibit excellent electrical conductivity and flexural modulus.

Here, the coated metal may be any metal having conductivity without limitation. The coated metal may include aluminum, stainless steel, iron, chrome, nickel, black nickel, copper, silver, gold, platinum, and the like. These may be used alone or in combination thereof. At least one coating layer may be formed.

The third filler is present in an amount of about 10 wt % to about 60 wt %, for example, about 15 wt % to about 50 wt %, preferably about 20 wt % to about 45 wt %, more preferably about 25 wt % to about 40 wt % in the total composite. Within this range, the composite has balance between conductivity, fluidity, impact strength, and flexural modulus.

In one embodiment, the amount of the third filler may be greater than or equal to that of the (A) thermoplastic resin. A weight ratio of the (A) thermoplastic resin to the (D) third filler may range from about 1:1 to about 1:1.5. Within this range, the composite has balance between rigidity and moldability.

In another embodiment, the third filler may be present in about 1 to 4 times the total amount of the first and second fillers. The amount of the third filler may be greater than the total amount of the first and second fillers. In one embodiment, a ratio of the (D) third filler to the sum of the first and second fillers (B+C) may be 1.8 to 2.5:1. Within this range, the composite can have excellent property balance.

(E) Functional Group-Containing Impact Modifier

According to the present invention, the composite may optionally include (E) a functional group-containing impact modifier. The (E) functional group-containing impact modifier has a structure in which a thermoplastic resin and a highly reactive functional group are grafted onto a rubber.

In one embodiment, the (E) functional group-containing impact modifier may be prepared by grafting a functional group, such as maleic anhydride, glycidyl (meth)acrylate, (meth)acrylic acid, oxazoline, and the like, onto a rubber, such as ethylene-propylene rubber, isoprene rubber, ethylene-octane rubber, ethylene-propylene-diene monomer, styrene-ethylene-butadiene-styrene, and combinations thereof. An intermediate block may be hydrogenated.

For example, the (E) functional group-containing impact modifier may include polyethylenemaleic anhydride-grafted (PE-g-MA), polypropylenemaleic anhydride-grafted (PP-g-MA), maleic anhydride-grafted ethylene-propylene rubber (EPR-g-MA), maleic anhydride-grafted ethylene-octane rubber (EOR-g-MA), maleic anhydride-grafted ethylene-propylene-diene monomer (EPDM-g-MA), acrylic acid-grafted polyethylene (PE-g-AA), acrylic acid-grafted ethylene-propylene rubber (EPR-g-AA), maleic anhydride-grafted ethylene-octane rubber (EOR-g-MA), acrylic acid-grafted ethylene-propylene-diene monomer (EPDM-g-AA), maleic anhydride-grafted styrene-ethylene-butadiene-styrene (SEBS-g-MA), and the like. These may be used alone or in combination thereof.

The (E) functional group-containing impact modifier is present in an amount of about 10 wt % or less, for example, about 1 wt % to about 10 wt %, preferably about 3 wt % to about 8 wt %, more preferably about 4 wt % to about 7.5 wt % in the total composite. Within this range, the composite can exhibit excellent impact strength and flexural modulus.

According to the present invention, the composite may further include an additive, such as flame retardants, plasticizers, coupling agents, heat stabilizers, light stabilizers, release agents, dispersants, anti-dripping agents, weather-resistant stabilizers, and the like.

According to the present invention, the composite may be molded by a typical molding method of a thermoplastic resin composition. For example, components are introduced into an extruder and prepared into pellets. The prepared pellets can be formed to various shapes through injection molding, compression molding, cast molding, or the like.

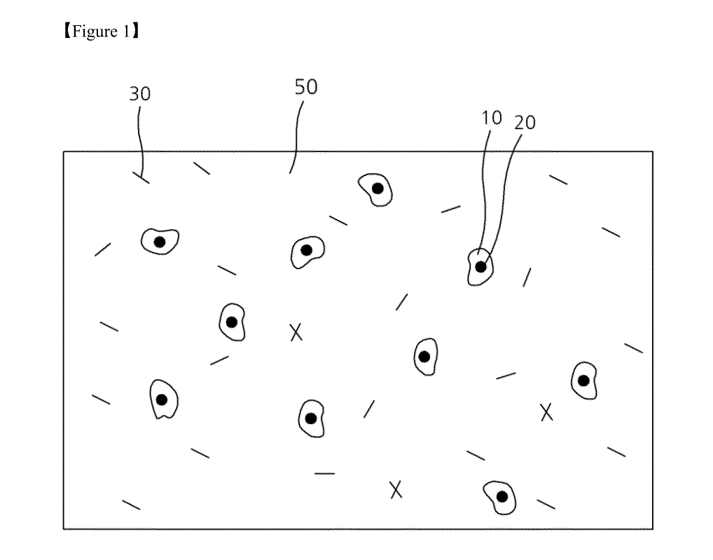

FIG. 1 is a schematic diagram of a composite according to one embodiment of the present invention. Referring to FIG. 1, the molded composite may have a structure, in which a thermoplastic resin 50 forms a continuous phase; first, second and third fillers 10, 20, 30 form a dispersed phase in the continuous phase; and the first filler 10 continuously or discontinuously surrounds a surface of the second filler 20.

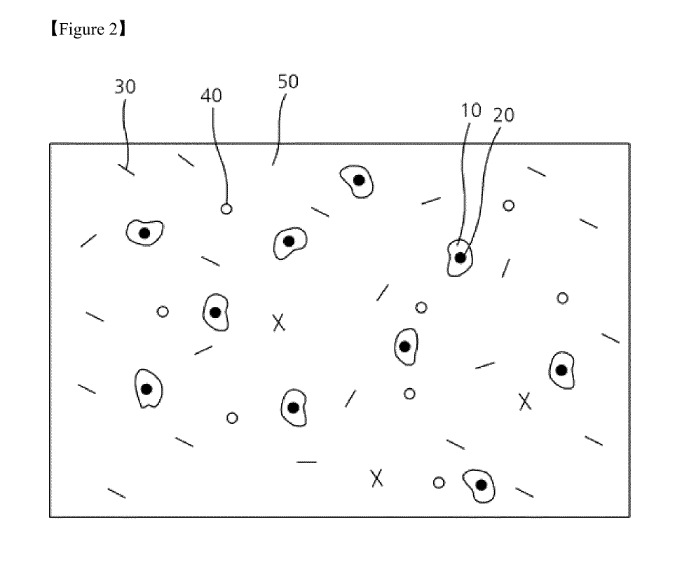

FIG. 2 is a schematic diagram of a composite according to another embodiment of the present invention. Referring to FIG. 2, the molded composite may have a structure, in which a thermoplastic resin 50 forms a continuous phase; first and second fillers 10, 20, carbon fiber 30, and a functional group-containing impact modifier 40 form a dispersed phase in the continuous phase; and the first filler 10 continuously or discontinuously surrounds a surface of the second filler 20.

According to the present invention, a molded product of the composite may have: a flexural modulus of about 25 GPa or more, as measured on a 3.2 mm specimen in accordance with ASTM D790; an EMI shielding effectiveness of about 40 dB or more, as measured at 1 GHz in accordance with ASTM D257; and a surface resistance of about 5.0Ω or less.

In one embodiment, the molded product may have: a flexural modulus of about 25 GPa or more, as measured on a 3.2 mm specimen in accordance with ASTM D790; an EMI shielding effectiveness of about 40 dB or more, as measured at 1 GHz in accordance with ASTM D257; and a surface resistance of about 3.0Ω or less.

In one embodiment, the molded product may have: a flexural modulus of about 25 GPa or more, as measured on a 3.2 mm specimen in accordance with ASTM D790; an Izod impact strength of about 8 kgf·cm/cm or more, as measured on a 3.2 mm specimen in accordance with ASTM D256; and a surface resistance of about 5.0Ω·cm or less, as measured at 1 GHz.

According to the invention, since the composite exhibits excellent properties in terms of electromagnetic shielding, conductivity, mechanical properties and moldability, the composite can be applied to LCD-protective brackets of portable displays, and various electromagnetic shielding materials.

Hereinafter, the present invention will be described in more detail with reference to some examples. It should be understood that these examples are provided for illustration only and are not to be in any way construed as limiting the present invention. A description of details apparent to those skilled in the art will be omitted for clarity.

### MODE FOR INVENTION

### Examples

Details of components used in Examples and Comparative Examples are as follows.

(A) Thermoplastic Resin

(A1) PA66 (ZYTEL 101 F, Dupont Co., Ltd.) having a melting point of 270° C. was used.

(A2) PA10T (TGP-3567, Evonik Co., Ltd.) having a melting point of 300° C. was used.

(A3) PET (A1100, Anychem Co., Ltd.) having a melting point of 260° C. was used.

(A4) PA (T600, Toyobo Co., Ltd.) having a melting point of 240° C. was used.

(B) First Filler

(B1) Solder powder (F05, Duksan Hi-Metal Co., Ltd.) having a melting point of 215° C. was used.

(B2) Solder powder (SA35, Duksan Hi-Metal Co., Ltd.) having a melting point of 220° C. was used.

(C) Second Filler

(C1) Silver-coated copper (SCC, Sunkyoung S.T Co., Ltd.) having a melting point of 1000° C. or more was used.

(C2) Nickel powder (1231, Sulzer Co., Ltd.) having a melting point of 1000° C. or more was used.

(C3) Nickel-coated graphite (2708, Sulzer Co., Ltd.) having a melting point of 900° C. or more was used.

(D) Third Filler

(D1) A PANEX PX35CA0250-65 (Zoltek Co., Ltd.), which was subjected to sizing with a polyurethane resin, and had a sizing content of 2.75% and a diameter of 7.2 μm, was used.

(D2) A nickel-coated carbon fiber (Tenax MC, Toho Co., Ltd.) was used.

(D3) HT C603 (Toho Tenex Co., Ltd.), which was subjected to sizing with a polyamide resin and had a sizing content of 3.5% and a diameter of 7.2 μm, was used.

(E) Impact Modifier

(E1) SEBS (KRATON G1651, SHELL Co., Ltd.) was used.

(E2) An S.B.S block copolymer (TUFPRENE A, ASAHI CHEM Co., Ltd.) was used.

(E3) EOR grafted with maleic anhydride (MA) (EOR-g-MA) (FUSABOND MN493D, DUPONT Co., Ltd.) was used.

(E4) SEBS grafted with maleic anhydride (MA) (SEBS-g-MA) (KRATON FG1901X, SHELL Co., Ltd.) was used.

(F) Heat stabilizer and Lubricant: IRGANOX1010 (CIBA chemical Co., Ltd.) as a heat stabilizer, and ethylene bis(stearamide) as a lubricant were mixed in a ratio of 1:1 and then used. 0.5 parts by weight of the mixture was added based on 100 parts by weight of the total amount of (A) to (E).

### Examples 1 to 9 and Comparative Examples 1 to 9

The components were mixed in amounts as listed in Tables 1 and 2 in a typical mixer, followed by extrusion using a twin-screw extruder having L/D=35 and Φ=45 mm, and prepared into pellets. The prepared pellets were dried at 100° C. for 4 hours, followed by preparing a specimen for measurement of properties and evaluation of EMI and resistivity at an injection molding temperature of 290° C. The specimen was left alone at 23° C. and 50% RH for 48 hours, followed by measuring properties thereof in accordance with ASTM standards.

Property Evaluation

(1) Flexural modulus: Flexural modulus was measured on a 6.4 mm thick specimen at 2.8 mm/min in accordance with ASTM D790 (unit: GPa).

(2) Specific gravity: Specific gravity was measured in accordance with ASTM D792.

(3) Spiral flow: The pellets were subjected to injection molding in a spiral-shaped mold having a thickness of 2 mm at a molding temperature of 320° C. and a mold temperature of 60° C. at an injection pressure of 50% at an injection rate of 70% using a 6 oz injection molding machine, followed by measuring the length of an injection-molded product (unit: mm).

(4) EMI shielding properties: A specimen was left alone at 23° C. and 50% RH for 48 hours, followed by measuring electromagnetic shielding effectiveness on the 2 t thick specimen (6×6) at 1 GHz in accordance with EMI D257 (unit: dB).

(5) Surface resistance: A copper tab having an area of 10 mm×10 mm was prepared, followed by measuring surface resistance on a 3.2 t thick injection-molded specimen using an Asahi 4201 resistance meter (unit: Ω·cm).

TABLE 1

| | | Example | | | | | | | | |
|---|---|---|---|---|---|---|---|---|---|---|
| | | 1 | 2 | 3 | 4 | 5 | 6 | 7 | 8 | 9 |
| Thermoplastic | A1 | 40 | 40 | 40 | 40 | 40 | — | — | 25 | 30 |
| resin | A2 | — | — | — | — | — | 40 | — | — | — |
| | A3 | — | — | — | — | — | — | 40 | — | — |
| | A4 | — | — | — | — | — | — | — | — | — |
| First filler | B1 | 10 | — | 10 | 10 | 10 | 10 | 10 | 25 | 10 |
| | B2 | — | 10 | — | — | — | — | — | — | — |
| Second filler | C1 | 10 | 10 | — | — | 10 | 10 | 10 | 10 | 20 |
| | C2 | — | — | 10 | — | — | — | — | — | — |
| | C3 | — | — | — | 10 | — | — | — | — | — |
| Third filler | D1 | 40 | 40 | 40 | 40 | — | 40 | 40 | 40 | 40 |
| | D2 | — | — | — | — | 40 | — | — | — | — |

| | | | | | | | | | |
|---|---|---|---|---|---|---|---|---|---|
| (F) Additive | 0.5 | 0.5 | 0.5 | 0.5 | 0.5 | 0.5 | 0.5 | 0.5 | 0.5 |
| Flexural modulus | 28 | 28 | 28 | 28 | 26 | 29 | 29 | 30 | 29 |
| (GPa) | | | | | | | | | |
| Specific gravity | 1.5 | 1.5 | 1.5 | 1.4 | 1.6 | 1.5 | 1.5 | 2.0 | 1.9 |
| Injection moldability | 250 | 250 | 250 | 250 | 245 | 240 | 280 | 230 | 220 |
| (mm) | | | | | | | | | |
| EMI shielding | 48 | 48 | 46 | 44 | 60 | 48 | 48 | 55 | 52 |
| effectiveness (dB) | | | | | | | | | |
| Surface resistance | 4.5 | 4.3 | 4.6 | 4.8 | 3.1 | 4.5 | 4.5 | 3.8 | 3.2 |
| (Ω) | | | | | | | | | |

TABLE 2

| | | Comparative Example | | | | | | | | |
|---|---|---|---|---|---|---|---|---|---|---|
| | | 1 | 2 | 3 | 4 | 5 | 6 | 7 | 8 | 9 |
| Thermoplastic | A1 | 50 | 40 | 50 | 80 | 75 | 20 | 10 | 64 | — |
| resin | A2 | — | — | — | — | — | — | — | | — |
| | A3 | — | — | — | — | — | — | — | | — |
| | A4 | — | — | — | — | — | — | — | | 40 |
| First filler | B1 | — | — | 10 | 10 | 10 | 10 | 10 | 10 | 10 |
| | B2 | — | — | — | — | — | — | — | | — |
| Second filler | C1 | 10 | 20 | — | 10 | 10 | 30 | 10 | 25 | 10 |
| | C2 | — | — | — | — | — | — | — | | — |
| | C3 | — | — | — | — | — | — | — | | — |
| Third filler | D1 | 40 | 40 | 40 | — | 5 | 40 | 70 | 1 | 40 |
| | D2 | — | — | — | — | — | — | — | | — |

| | | | | | | | | | |
|---|---|---|---|---|---|---|---|---|---|
| (F) Additive | 0.5 | 0.5 | 0.5 | 0.5 | 0.5 | 0.5 | 0.5 | 0.5 | 0.5 |
| Flexural modulus | 26 | 27 | 25 | 2 | 4 | 28 | 36 | 3 | 29 |
| (GPa) | | | | | | | | | |
| Specific gravity | 1.4 | 1.6 | 1.4 | 1.4 | 1.5 | 2.2 | 1.7 | 1.7 | 1.5 |
| Injection | 270 | 220 | 280 | 320 | 310 | 120 | 130 | 380 | 265 |
| moldability (mm) | | | | | | | | | |
| EMI shielding | 42 | 45 | 41 | 20 | 22 | 53 | 57 | 28 | 48 |
| effectiveness (dB) | | | | | | | | | |
| Surface resistance | 10.2 | 8.2 | 7.9 | 67.2 | 62.3 | 2.8 | 4.1 | 12.5 | 10.2 |
| (Ω) | | | | | | | | | |

In Table 2, it could be seen that the specimens of Examples 1 to 9 had a flexural modulus of about 25 GPa or more, an injection moldability (320° C.) of 200 mm or more, an EMI shielding effectiveness of 40 dB or more, and a surface resistance of about 5.0Ω or less.

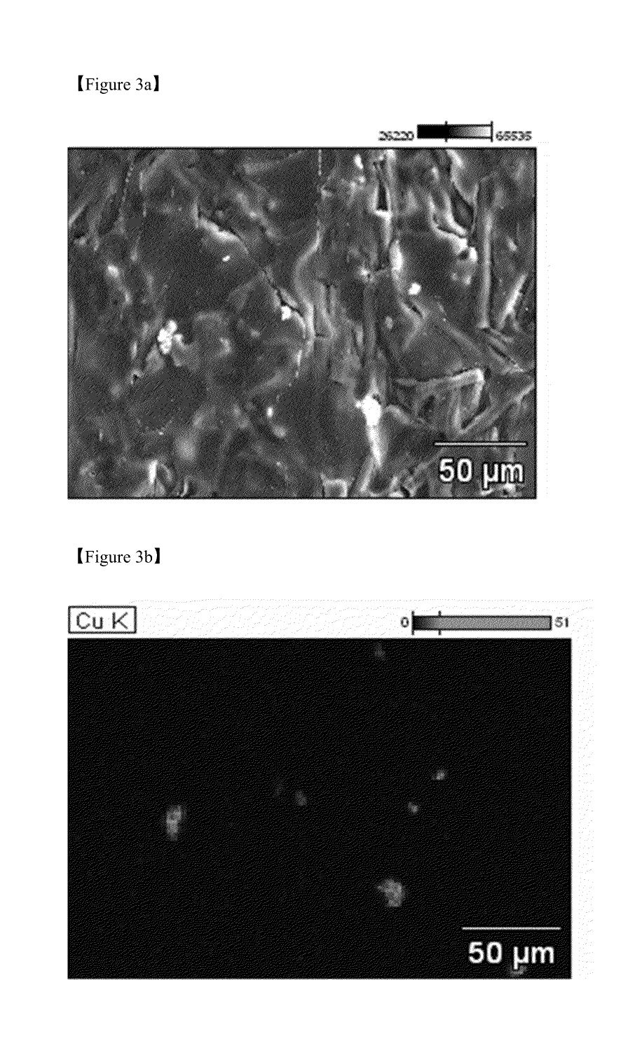

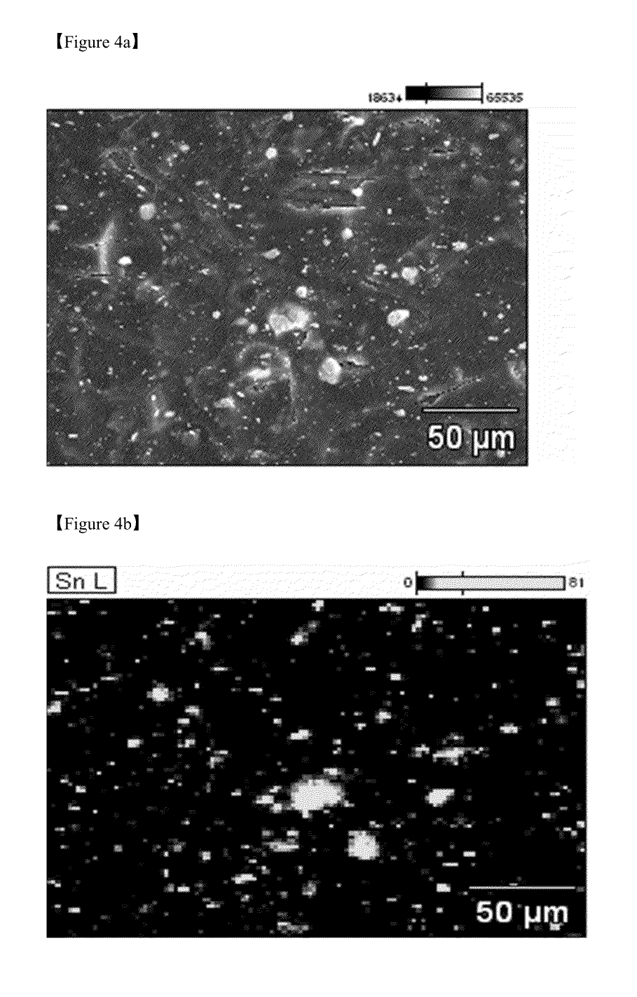

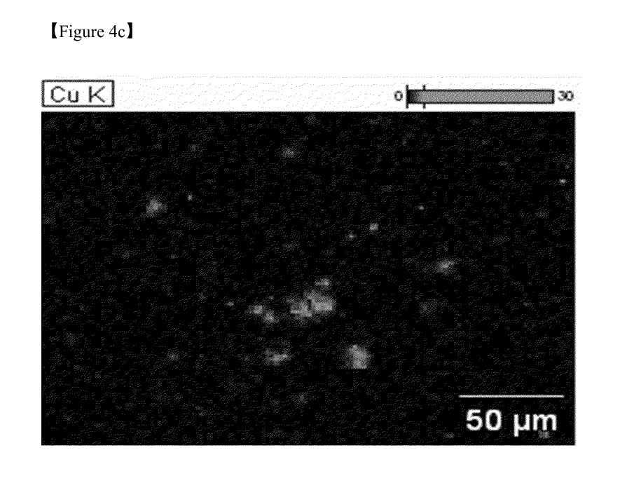

FIG. 3 shows (a) a scanning electron microscope (SEM) image of a surface of the specimen of Comparative Example 1, and (b) an energy dispersive spectroscopy (EDS) image of a surface of copper (Cu). In addition, FIG. 4 shows (a) a SEM image of a surface of the specimen of Example 1, (b) an EDS image of a surface of tin (Sn), and (c) an EDS image of a surface of copper (Cu). Tin was not detected on the surface of the specimen of Comparative Example 1.

In Example 1 and Comparative Example 1, it can be seen that the specimen free from the first filler included a small amount of the second filler aligned on the surface thereof. In addition, it can be seen that the specimen free from the first filler had a surface resistance of 5.0Ω or more.

Further, in Example 2 and Comparative Example 2, it can be seen that, even though the second filler was present in an amount (20 wt %) corresponding to the sum of the amounts (each 10 wt %) of the first and second fillers of the specimen of Example 2 in the specimen of Comparative Example 2, the specimen of Comparative Example 2 had insufficient electrical conductivity out of the range according to the present invention, as compared with the specimen of Example 2.

It can be seen that the specimen using the first filler alone as in Comparative Example 3 also had insufficient electrical conductivity out of the range according to the present invention. That is, it can be seen that, when both the first and second fillers were used, the specimen exhibited reduced surface resistance and improved electrical conductivity due to alignment of metallic components of the first and second fillers on the surface of the specimen.

The specimen, in which the conductive fiber filler was not present or was present in an amount of less than 10 wt % as in Comparative Examples 4 to 5, could not exhibit desired properties, such as flexural rigidity, EMI shielding properties, electrical conductivity, and the like. When the specimen contained an excess of the second filler as in Comparative Example 6, or contained greater than 60 wt % of the third filler as in Comparative Example 7, there was a problem in injection moldability.

It can be seen that when the second and third fillers were present in amounts out of the ranges according to the present invention in the specimen as in Comparative Example 9, the specimen had significantly deteriorated flexural strength and shielding effectiveness, and high surface resistance.

When the first filler did not have a lower melting point than the thermoplastic resin by 30° C. or more, the specimen exhibited reduced electrical conductivity on the surface thereof, since the metallic components of the first and second fillers were not aligned on the surface thereof.

As such, in Examples 1 to 9 and Comparative Examples 1 to 9, it could be seen that the specimens exhibited properties in a desired level or higher when the components were present in amounts within the ranges according to the present invention.

### Examples 10 to 14 and Comparative Examples 10 to 12

### Use of Surface-Treated Carbon Fiber

The same process was performed as in Examples 1 to 9 and Comparative Examples 1 to 9 except that the amounts of the components were changed as listed in Tables 3 and 4. The prepared specimens were evaluated as to the following properties.

(1) Flexural modulus: Flexural modulus was measured on a 3.2 mm thick specimen at 1.4 mm/min in accordance with ASTM D790 (unit: GPa).

(2) Specific gravity: Specific gravity was measured in accordance with ASTM D792.

(3) Spiral flow: The pellets were subjected to injection molding in a spiral-shaped mold having a thickness of 2 mm at a molding temperature of 320° C. and a mold temperature of 60° C. at an injection pressure of 50% at an injection rate of 70% using a 6 oz injection molding machine, followed by measuring the length of an injection-molded product (unit: mm).

(4) EMI shielding properties: A specimen was left alone at 23° C. and 50% RH for 48 hours, followed by measuring electromagnetic shielding effectiveness on the 2 t thick specimen (6×6) at 1 GHz in accordance with EMI D257 (unit: dB).

(5) Surface resistance: A copper tab having an area of 10 mm×10 mm was prepared, followed by measuring surface resistance on a 3.2 t thick injection-molded specimen using an Asahi 4201 resistance meter (unit: Ω).

(6) Volume resistivity: Volume resistivity was measured on a 3.2 t thick injection-molded specimen in accordance with ASTM D257.

TABLE 3

| | | Example | | | | |
|---|---|---|---|---|---|---|
| | | 10 | 11 | 12 | 13 | 14 |
| (A) | (A1) | 30 | 30 | 35 | 35 | 35 |
| Thermoplastic | (A4) | — | — | — | — | — |
| resin | | | | | | |
| (B2) First filler | | 20 | 20 | 20 | 15 | 17 |
| (C1) Second filler | | 10 | 10 | 15 | 10 | 8 |
| (D) Third filler | (D2) | — | 40 | — | 20 | 20 |
| | (D3) | 40 | — | 30 | 20 | 20 |

| | | | | | |
|---|---|---|---|---|---|
| (F) Additive | 0.5 | 0.5 | 0.5 | 0.5 | 0.5 |
| Flexural modulus (GPa) | 26 | 26 | 26 | 28 | 27 |
| Specific gravity | 1.8 | 1.8 | 1.7 | 1.7 | 1.7 |
| Spiral flow (mm) | 220 | 220 | 230 | 250 | 240 |
| EMI shielding | 56 | 61 | 49 | 50 | 49 |
| effectiveness (dB) | | | | | |
| Surface resistance (Ω) | 1.8 | 1.5 | 2.3 | 2.2 | 2.2 |
| Volume resistivity | 0.18 | 0.15 | 0.25 | 0.28 | 0.26 |
| (Ω · cm) | | | | | |

TABLE 4

| | | Comparative Example | | |
|---|---|---|---|---|
| | | 10 | 11 | 12 |
| (A) Thermoplastic resin | (A1) | 40 | 40 | — |
| | (A4) | — | — | 30 |
| (B2) First filler | | 20 | — | 20 |
| (C1) Second filler | | — | 20 | 10 |
| (D) Third filler | (D2) | — | — | — |
| | (D3) | 40 | 40 | 40 |

| | | | |
|---|---|---|---|
| (F) Additive | 0.5 | 0.5 | 0.5 |
| Flexural modulus (GPa) | 29 | 28 | 24 |
| Specific gravity | 1.7 | 1.7 | 1.8 |
| Spiral flow (mm) | 250 | 250 | 220 |
| EMI shielding effectiveness (dB) | 40 | 41 | 38 |
| Surface resistance (Ω) | 3.8 | 4.0 | 5.0 |
| Volume resistivity (Ω · cm) | 0.40 | 0.45 | 0.45 |

In Tables 3 and 4, it can be seen that the specimens of Examples 10 to 14 exhibited a flexural modulus of about 25 GPa or more, an EMI shielding effectiveness of 40 dB or more, and a surface resistance of 3.0Ω or less, which were excellent.

Conversely, it can be seen that the specimen of Comparative Example 10, which did not use the second filler, and the specimen of Comparative Example 11, which did not use the first filler, exhibited low electrical conductivity. In addition, the specimen of Comparative Example 12 having a difference in melting point between the (A) thermoplastic resin and the (B) first metallic filler of less than 30° C. exhibited poor electrical conductivity.

### Examples 15 to 20 and Comparative Examples 13 to 15

### Use of Functional Group-Containing Impact Modifier

The same process was performed as in Examples 1 to 9 and Comparative Examples 1 to 9 except that the amounts of the components were changed as listed in Tables 5 and 6. The prepared specimens were evaluated as to the following properties.

(1) Flexural modulus: Flexural modulus was measured on a 3.2 mm thick specimen at 1.4 mm/min in accordance with ASTM D790 (unit: GPa).

(2) Specific gravity: Specific gravity was measured in accordance with ASTM D792.

(3) Izod impact strength (unnotched): Izod impact strength was measured on a 3.2 mm thick specimen at 23° C. in accordance with ASTM D256 (unit: kgf·cm/cm).

(4) Spiral flow: The pellets were subjected to injection molding in a spiral-shaped mold having a thickness of 2 mm at a molding temperature of 320° C. and a mold temperature of 60° C. at an injection pressure of 50% at an injection rate of 70% using a 6 oz injection molding machine, thereby measuring length of an injection-molded product (unit: mm).

(5) EMI shielding properties: A specimen was left alone at 23° C. and 50% RH for 48 hours, followed by measuring electromagnetic shielding effectiveness on the 1 t thick specimen (6×6) at 1 GHz in accordance with EMI D257 (unit: dB).

(6) Surface resistance: A copper tab having an area of 10 mm×10 mm was prepared, followed by measuring surface resistance on a 3.2 t thick injection-molded specimen using an Asahi 4201 resistance meter (unit: Ω·cm).

TABLE 5

| | | Example | | | | | |
|---|---|---|---|---|---|---|---|
| | | 15 | 16 | 17 | 18 | 19 | 20 |
| (A) Thermoplastic | (A1) | 35 | 35 | 35 | — | 30 | 35 |
| resin | (A2) | — | — | — | 35 | — | — |
| (B1) First filler | | 10 | 10 | 10 | 10 | 10 | 9 |
| (C) Second filler | (C1) | 10 | 10 | — | — | — | 11 |
| | (C2) | — | — | 10 | 10 | 10 | — |
| (D1) Third filler | | 40 | 40 | 40 | 40 | 40 | 40 |
| (E) Impact modifier | (E1) | — | — | — | — | — | — |
| | (E2) | — | — | — | — | — | — |
| | (E3) | — | 5 | — | 5 | — | — |
| | (E4) | 5 | — | 5 | — | 10 | 5 |

| | | | | | | |
|---|---|---|---|---|---|---|
| (F) Additive | 0.5 | 0.5 | 0.5 | 0.5 | 0.5 | 0.5 |
| Flexural modulus (GPa) | 28 | 27 | 28 | 28 | 25 | 26 |
| Specific gravity | 1.5 | 1.5 | 1.6 | 1.5 | 1.4 | 1.4 |
| IZOD impact strength | 9.8 | 8.9 | 9.6 | 8.5 | 10.5 | 9.7 |
| (kgf · cm/cm) | | | | | | |
| Spiral flow (mm) | 250 | 250 | 245 | 250 | 250 | 250 |
| EMI shielding effectiveness | 48 | 48 | 46 | 44 | 42 | 44 |
| (dB) | | | | | | |
| Surface resistance (Ω) | 3.3 | 3.4 | 3.1 | 3.2 | 3.5 | 3.8 |

TABLE 6

| | | Comparative Example | | |
|---|---|---|---|---|
| | | 13 | 14 | 15 |
| (A) Thermoplastic resin | A1 | 45 | 35 | 45 |
| | A2 | — | — | — |
| (B) First filler | | — | 20 | 20 |
| (C) Second filler | C1 | 10 | — | 20 |
| | C2 | — | — | — |
| (D) Carbon fiber | | 40 | 40 | — |
| (E) Impact modifier | (E1) | — | — | — |
| | (E2) | — | — | — |
| | (E3) | — | — | — |
| | (E4) | 5 | 5 | 15 |

| | | | |
|---|---|---|---|
| (F) Additive | 0.5 | 0.5 | 0.5 |
| Flexural modulus (GPa) | 26 | 27 | 11 |
| Specific gravity | 1.4 | 1.6 | 2.5 |
| IZOD impact strength (kgf · cm/cm) | 10.1 | 9.6 | 14.1 |
| Spiral flow (mm) | 270 | 250 | 265 |
| EMI shielding effectiveness (dB) | 35 | 37 | 23 |
| Surface resistance (Ω) | 51.6 | 5.8 | 28.4 |

In Tables 5 and 6, it can be seen that the specimens of Examples 15 to 20 exhibited a flexural modulus of about 25 GPa or more, an EMI shielding effectiveness of 40 dB or more, a surface resistance of 5.0Ω or less, an Izod impact strength of 8 kgf·cm/cm or more, and a spiral flow (320° C.) of 200 mm or more, which were excellent.

In Example 15 and Comparative Example 13, it can be seen that the specimen free from the (B) first filler included a smaller amount of the (C) second filler aligned on the surface thereof, and thus exhibited increased surface resistance. It can be seen that the specimen of Comparative Example 14, which did not use the (C) second filler, exhibited increased resistance and deteriorated EMI shielding effectiveness. The specimen of Comparative Example 15, which did not use the (D) carbon fiber, exhibited significantly deteriorated flexural modulus and rapidly increased surface resistance, and thus exhibited poorer shielding performed than any other specimens.

Although some embodiments have been described above, it should be understood that the present invention is not limited to these embodiments and may be embodied in different ways, and that various modifications, changes, and alterations can be made by those skilled in the art without departing from the spirit and scope of the present invention. Therefore, the scope of the invention should be limited only by the accompanying claims and equivalents thereof.

1. A composite comprising:
about 10 wt % to about 84 wt % of (A) a thermoplastic resin;
about 5 wt % to about 35 wt % of (B) a first filler;
about 1 wt % to about 20 wt % of (C) a second filler; and
about 10 wt % to about 60 wt % of (D) a third filler,
wherein the third filler is a conductive fiber, and the (A) thermoplastic resin, the (B) first filler and the (C) second filler have melting points satisfying Relation 1:
Tma−30° C.>Tmb,Tma+500° C.<Tmc [Relation 1]
wherein Tma is the melting point (° C.) of the (A) thermoplastic resin, Tmb is the melting point (° C.) of the (B) first filler, and Tmc is the melting point (° C.) of the (C) second filler.

2. The composite according to claim 1, wherein the third filler is present in an amount of about 1 to 4 times a total amount of the first and second fillers.

3. The composite according to claim 1, wherein the third filler is present in an amount of greater than a total amount of the first and second fillers.

4. The composite according to claim 1, wherein the second filler has higher electrical conductivity than the first filler.

5. The composite according to claim 1, wherein the second filler has a powder or fiber form.

6. The composite according to claim 1, wherein a weight ratio of the (B) first filler to the (C) second filler ranges from about 1:1 to about 3:1.

7. The composite according to claim 1, wherein the third filler is carbon fiber or surface-treated carbon fiber.

8. The composite according to claim 7, wherein the surface-treated carbon fiber is carbon fiber having a surface subjected to coating with a metal or sizing with a resin.

9. The composite according to claim 8, wherein the metal coated onto the carbon fiber comprises at least one selected from the group consisting of aluminum, stainless steel, iron, chrome, nickel, black nickel, copper, silver, gold, and platinum.

10. The composite according to claim 1, wherein the third filler has a diameter from about 3 μm to about 10 μm.

11. The composite according to claim 1, wherein the (A) thermoplastic resin is a crystalline thermoplastic resin.

12. The composite according to claim 1, wherein the (A) thermoplastic resin comprises at least one of polyacetal, acrylic, polycarbonate, aromatic vinyl, polyester, vinyl, polyphenylene ether, polyolefin, acrylonitrile-butadiene-styrene copolymer, polyarylate, polyamide, polyamideimide, polyether, polysulfide, polyarylsulfone, polyetherimide, polyethersulfone, polyphenylene sulfide, fluorine, polyimide, polyetherketone, polybenzoxazole, polyoxadiazole, polybenzothiazole, polybenzimidazole, polypyridine, polytriazole, polypyrrolidine, polydibenzofuran, polysulfone, polyurea, polyphosphazene, and liquid crystal polymer resins.

13. The composite according to claim 1, further comprising: at least one additive selected from the group consisting of flame retardants, plasticizers, coupling agents, heat stabilizers, light stabilizers, release agents, dispersants, anti-dripping agents, and weather-resistant stabilizers.

14. The composite according to claim 1, wherein the (D) third filler is present in an amount of greater than or equal to the amount of the (A) thermoplastic resin.

15. The composite according to claim 1, further comprising: (E) a functional group-containing impact modifier.

16. The composite according to claim 15, wherein the (E) functional group-containing impact modifier is functionalized through graft polymerization with maleic anhydride, glycidyl (meth)acrylate, (meth)acrylic acid, or oxazoline.

17. The composite according to claim 1, wherein the first filler has a lower melting point than the second filler by about 700° C. or more.

18. A molded product of the composite according to claim 1, the molded product having a structure, in which a thermoplastic resin forms a continuous phase; a dispersed phase comprising the first, second and third fillers is dispersed in the continuous phase; the first filler has a lower melting point than the second filler by about 700° C. or more; and the first filler continuously or discontinuously surrounds a surface of the second filler.

19. The molded product according to claim 18, wherein the molded product has a flexural modulus of about 25 GPa or more, as measured on a 3.2 mm thick specimen in accordance with ASTM D790; an EMI shielding effectiveness of about 40 dB or more, as measured at 1 GHz in accordance with ASTM D257; and a surface resistance of about 5.0Ω·cm or less.
